(19) United States
(12) Patent Application Publication
(10) Pub. No.: US 2010/0214371 A1
(43) Pub. Date: Aug. 26, 2010

(54) LIQUID EJECTING HEAD, LIQUID EJECTING APPARATUS, AND METHOD OF MANUFACTURING LIQUID EJECTING HEAD

(75) Inventor: Noriaki Okazawa, Shiojiri-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Shinjuku-ku (JP)

(21) Appl. No.: 12/710,289

(22) Filed: Feb. 22, 2010

(30) Foreign Application Priority Data
Feb. 24, 2009 (JP) 2009-041561

(51) Int. Cl. B41J 2/045; H01L 41/22

(52) U.S. Cl. 347/70; 29/25.35

(57) ABSTRACT

A liquid ejecting head includes a flow channel forming substrate in which a plurality of pressure generating chambers in communication with nozzles which eject liquid droplets are juxtaposed to each other; a diaphragm which is provided on the flow channel forming substrate and constitutes one side surface of the pressure generating chamber; and piezoelectric elements which are provided so that their leading ends abut on the diaphragm, wherein the diaphragm includes a first vibrating member and a second vibrating member disposed between the first vibrating member and the flow channel forming substrate, the first vibrating member is formed from a first composite plate made up of a first sheet member and a first supporting plate and has a first island portion which is constructed from the first supporting plate and on which a leading end of the piezoelectric element abuts, and the second vibrating member is formed from a second composite plate made up of a second sheet member and a second supporting plate and has a second island portion which is constructed from the second supporting plate and arranged at a portion opposite to the first island portion.

### BACKGROUND

1. Technical Field

The present invention relates to a liquid ejecting head which ejects liquid droplets from a nozzle, a liquid ejecting apparatus, and a method of manufacturing the liquid ejecting head.

2. Related Art

As a liquid ejecting head which discharges liquid droplets, for example, there is an ink jet recording head in which a part of a pressure generating chamber in communication with a nozzle which ejects ink droplets is formed from a diaphragm and the diaphragm is deformed by a piezoelectric element to pressurize the ink in the pressure generating chamber so as to discharge ink droplets from the nozzle. As an example of such an ink jet recording head, that using a piezoelectric actuator of longitudinal vibration mode which expands and contracts in an axial direction of the piezoelectric element is in practical use. Specifically, for example, an ink jet recording head in which a nozzle plate provided with a nozzle is bonded to one side of a first layer forming a pressure chamber is formed, an intermediate layer is bonded to the other side of the first layer, and a leading end of a piezoelectric element as a pressure generating unit is abutted on an island portion (an island-like portion) provided on the intermediate layer is known (see, for example, JP-A-2001-277524).

In such an ink jet recording head, as the density of nozzles has increased recently, the width of the island portion on which the piezoelectric element abuts has gradually narrowed. As the width of the island portion narrows, there occurs a problem that the rigidity of the island portion is lowered, and thus it is not possible to ensure displacement of the diaphragm upon driving the piezoelectric element. That is, there is a problem that it is not possible to eject ink droplets from the nozzle with desired characteristics (ejecting speed, ejecting amount and the like).

In addition, although it is conceivable to increase thickness of the island portion in order to ensure rigidity of the island portion, there is also a problem that in the case of providing the island portion at a high density, it is very difficult to manufacture the island portion.

Furthermore, these problems are present in the liquid ejecting head which ejects other liquid droplets just as they are present in the ink jet recording head which ejects ink droplets from nozzle.

### SUMMARY

An advantage of some aspects of the invention is to provide a liquid ejecting head, a liquid ejecting apparatus, and a method of manufacturing the liquid ejecting head which can maintain favorable liquid droplet ejecting characteristics even with a relatively high density of nozzle.

According to a first aspect of the invention, there is provided a liquid ejecting head including: a flow channel forming substrate in which a plurality of pressure generating chambers in communication with nozzles which eject liquid droplets are juxtaposed to each other; a diaphragm which is provided on the flow channel forming substrate and constitutes one side surface of the pressure generating chamber; and piezoelectric elements which are provided so that their leading ends abut on the diaphragm, wherein the diaphragm includes a first vibrating member and a second vibrating member disposed between the first vibrating member and the flow channel forming substrate, the first vibrating member is formed from a first composite plate made up of a first sheet member and a first supporting plate and has a first island portion which is constructed from the first supporting plate and on which a leading end of the piezoelectric element abuts, and the second vibrating member is formed from a second composite plate made up of a second sheet member and a second supporting plate and has a second island portion which is constructed from the second supporting plate and arranged at a portion opposite to the first island portion.

In this aspect of the invention, since the first island portion is arranged at an area opposite to the second island portion, rigidity of the second island portion is substantially improved. With this configuration, the diaphragm can be favorably deformed by driving the piezoelectric element.

Hereupon, it is preferable that the width of the first island portion is wider than the width of the second island portion at least in a juxtaposing direction of the pressure generating chambers. With this configuration, the first island portion can be relatively easily arranged opposite to the second island portion.

In addition, it is preferable that the first sheet member is provided with a through hole and a space defined between the first vibrating member and the second vibrating member is vented to the atmosphere by the through hole. With this configuration, deformation or breakage of the first and second sheet members that occurs if air in the space expands due to heating in the manufacturing process can be prevented.

In addition, it is preferable that the first vibrating member has a first thin-walled portion constructed from the first sheet member at a periphery of the first island portion and the second vibrating member has a second thin-walled portion constructed from the second sheet member at a periphery of the second island portion, and the width of the first thin-walled portion is wider than the width of the second thin-walled portion. With this configuration, deformation of the second vibrating member is not regulated by the first vibrating member, and the diaphragm can be favorably deformed by driving the piezoelectric element.

In addition, according to another aspect of the invention, there is provided a liquid ejecting apparatus including the above liquid ejecting head. With this invention, it is possible to realize a liquid ejecting apparatus which has an improved reliability.

Furthermore, there is provided a method of manufacturing a liquid ejecting head including: a flow channel forming substrate in which a plurality of pressure generating chambers in communication with nozzles which eject liquid droplets are juxtaposed to each other; a diaphragm which is provided on the flow channel forming substrate and constitutes one side surface of the pressure generating chamber; and piezoelectric elements which are provided so that their leading ends abut on the diaphragm, wherein the diaphragm includes a first vibrating member and a second vibrating member disposed between the first vibrating member and the flow channel forming substrate, the first vibrating member is formed from a first composite plate made up of a first sheet member and a first supporting plate and has a first island portion which is constructed from the first supporting plate and on which the leading end of the piezoelectric element abuts, and the second vibrating member is formed from a second composite plate made up of a second sheet member and a second supporting plate and has a second island portion which is constructed from the second supporting plate and arranged at a portion opposite to the first island portion, the method including: forming the second vibrating member on a wafer for the flow channel forming substrate in which a plurality of the flow channel forming substrates are integrally formed; forming the first vibrating member on the second vibrating member; and dividing the wafer for the flow channel forming substrate, wherein in a step of forming the second vibrating member, after bonding the second composite plate made up of the second sheet member and the second supporting plate onto the wafer for the flow channel forming substrate, a mask member is positioned with taking an alignment mark provided on the wafer for the flow channel forming substrate as a reference, and the second island portion is formed by etching the second supporting plate through the mask member.

With this configuration, it is possible to form the second island portion with high accuracy with respect to the pressure generating chamber. Accordingly, it is possible to displace the diaphragm favorably by driving the piezoelectric element and manufacture a liquid ejecting head having improved liquid droplet ejecting characteristics.

### BRIEF DESCRIPTION OF THE DRAWINGS

The invention will be described with reference to the accompanying drawings, wherein like numbers reference like elements.

FIG. 1 is a sectional view showing a recording head according to a first embodiment of the invention.

FIGS. 2A and 2B are enlarged sectional views showing a main portion of the recording head according to the first embodiment of the invention.

FIG. 3 is a plan view showing a first vibrating member according to the first embodiment of the invention.

FIG. 4 is a plan view showing a second vibrating member according to the first embodiment of the invention.

FIG. 5 is a sectional view showing a deforming state of a diaphragm.

FIG. 6 is a plan view showing a method of manufacturing the recording head according to the first embodiment of the invention.

FIGS. 7A, 7B and 7C are sectional views showing a method of manufacturing the recording head according to the first embodiment of the invention.

FIG. 8 is a plan view showing a modified example of a method of manufacturing the recording head.

FIG. 9 is a perspective view schematically showing a recording apparatus according to an embodiment of the invention.

### DESCRIPTION OF EXEMPLARY EMBODIMENTS

Hereinafter, embodiments of the invention will be described with reference to the accompanying drawings.

### First Embodiment

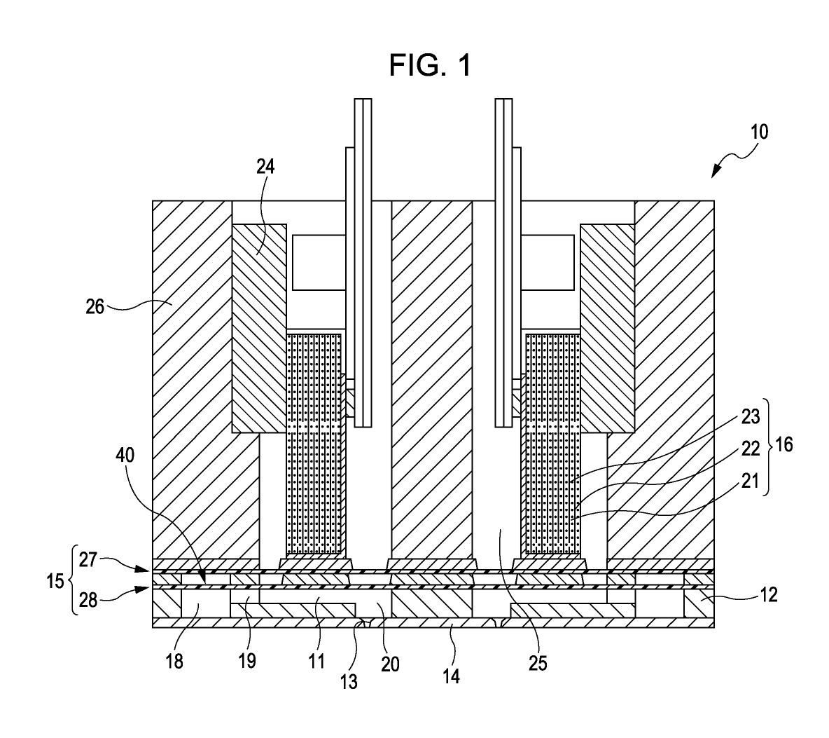

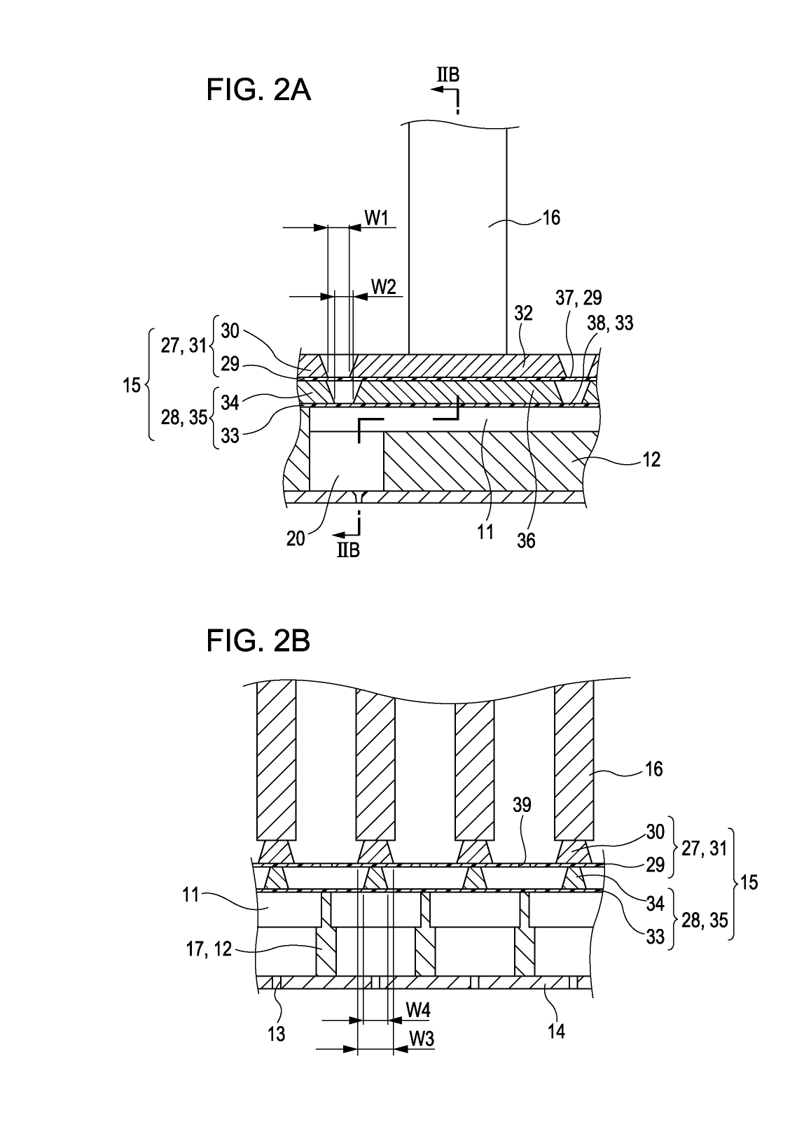

As shown in FIGS. 1, 2A and 2B, an ink jet recording head 10 as an example of liquid ejecting head includes a flow channel forming substrate 12 having a plurality of pressure generating chambers 11, a nozzle plate 14 in which a plurality of nozzles 13 each connected with a corresponding one of the pressure generating chambers 11 are bored, a diaphragm 15 which is arranged at a side of the flow channel forming substrate 12 opposite to the nozzle plate 14, and a piezoelectric element 16 which is arranged at an area on the diaphragm 15 corresponding to each of the pressure generating chambers 11.

The flow channel forming substrate 12 is provided with pressure generating chambers 11 on a surface layer portion at its one side, the pressure generating chambers 11 being divided by a partitioning wall 17 and juxtaposed to each other in a width direction of the substrate. For example, in this embodiment, the plural pressure generating chambers 11 are provided in two lines in the flow channel forming substrate 12. In addition, a reservoir 18 for supplying ink to each of the pressure generating chambers 11 is provided at the outside of each row of the pressure generating chambers 11 in a state of passing through the flow channel forming substrate 12 in its thickness direction. Then, each of the pressure generating chambers 11 is connected with each of the reservoir 18 via an ink supplying path 19. In this embodiment, the ink supplying path 19 is formed in a width narrower than the width of the pressure generating chamber 11 and plays a role in maintaining a constant flow channel resistance to ink flowing into the pressure generating chamber 11 from the reservoir 18. Furthermore, a nozzle communication hole 20 passing through the flow channel forming substrate 12 is formed at an end side of the pressure generating chamber 11 opposite to the reservoir 18. Materials used in such a flow channel forming substrate 12 are not particularly limited, but in this embodiment, a silicon single crystal substrate is used. The flow channel of the pressure generating chamber 11 or the like is formed by etching the flow channel forming substrate (the silicon single crystal substrate) 12.

A nozzle plate 14 into which nozzles 13 are bored is adhered to one side surface of the flow channel forming substrate 12 via an adhesive or a thermal welded film. Each of nozzles 13 is connected with each of the pressure generating chambers 11 via the nozzle communication hole 20 provided in the flow channel forming substrate 12.

In addition, a diaphragm 15 is bonded to the other side of the flow channel forming substrate 12, i.e. an opening surface side of the pressure generating chamber 11, and each of the pressure generating chambers 11 is sealed by the diaphragm 15. A piezoelectric element 16 as a pressure generating unit which generates pressure for ejecting ink droplets into the pressure generating chamber 11 is fixed on the diaphragm 15 in a state that a leading end of the piezoelectric element 16 abuts on the diaphragm 15. Specifically, the piezoelectric element 16 is constructed from an active area which contributes to vibration and an inactive area which does not contribute to vibration, in which a leading end of the active area abuts on the diaphragm 15.

In this embodiment, the piezoelectric element 16 is configured such that a piezoelectric material 21 and electrode forming materials 22 and 23 are longitudinally and alternately stacked like a sandwich, and the inactive area which does not contribute to vibration is fixed to a fixing substrate 24. In addition, in this embodiment, a head case 26 having a piezoelectric element holding portion 25 which can seal a space in a state that the space is ensured to the extent that does not inhibit movement of the piezoelectric element 16 is fixed on the diaphragm 15. Moreover, the fixing substrate 24 to which the piezoelectric element 16 is fixed is fixed to the head case 26 on a side opposite to the piezoelectric element 16.

Hereupon, the diaphragm 15 on which a leading end of the piezoelectric element 16 abuts includes a first vibrating member 27 and a second vibrating member 28 which is disposed between the first vibrating member 27 and the flow channel forming substrate 12. As shown in an enlarged view of FIGS. 2A and 2B, the first vibrating member 27 is formed from a first composite plate 31 made up of a first sheet member 29 and a first supporting plate 30 and has a first island portion 32 which is constructed from the first supporting plate 30 and on which a leading end of the piezoelectric element 16 abuts. On the other hand, the second vibrating member 28 is formed from a second composite plate 35 made up of a second sheet member 33 and a second supporting plate 34 and has a second island portion 36 which is constructed from the second supporting plate 34 and arranged at a portion opposite to the first island portion 32. Then, the second vibrating member 28 is bonded to the flow channel forming substrate 12 at the second sheet member 33 side and the first vibrating member 27 is bonded to the second vibrating member 28 at the first sheet member 29 side, thereby the diaphragm 15 is constructed.

The first sheet member 29 and the second sheet member 33 are, for example, composed of an elastic member such as a resin film. On the other hand, the first supporting plate 30 and the second supporting plate 34 are, for example, composed of metal material. In this embodiment, the first and second sheet members 29 and 33 are composed of PPS (Polyphenylenesulfide) film having a thickness of several micrometers and the first and second supporting plate 30 and 34 are composed of stainless steel plate (SUS) having a thickness of several tens of micrometers. As the first and second sheet members 29 and 33, materials such as polysulfone, polycarbonate, polyetheretherketone, acrylonitrile-butadiene-styrene copolymer as well as PPS may be used. In addition, the first and second supporting plates 30 and 34 may use nickel and the like as well as the stainless steel plate.

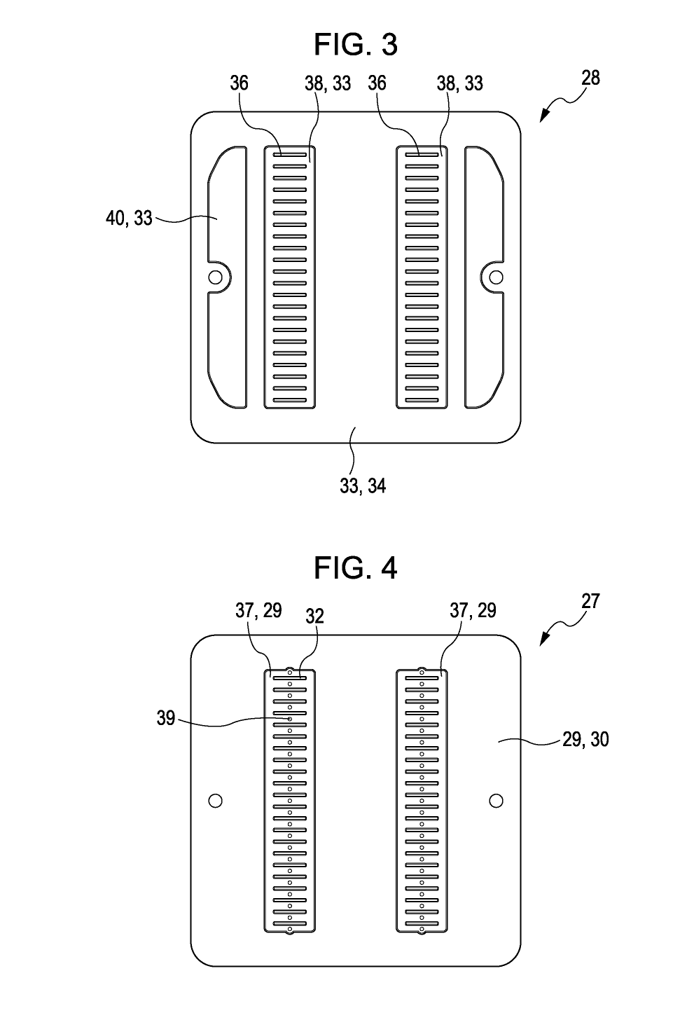

In the first vibrating member 27 having such a constitution, the first island portion 32 on which the leading end of the piezoelectric element 16 abuts as described above is provided. That is, as shown in FIGS. 2A, 2B and 3, a first thin-walled portion 37 which is substantially constructed from the first sheet member 29 is formed at an area of the first vibrating member 27 opposite to the periphery of each pressure generating chamber 11, and the first island portion 32 is provided at an inside of the first thin-walled portion 37. In addition, as shown in FIGS. 2A, 2B and 4, just like the first vibrating member 27, a second thin-walled portion 38 which is substantially constructed from the second sheet member 33 is formed at an area of the second vibrating member 28 opposite to the periphery of each pressure generating chamber 11, and the second island portion 36 is provided at an inside of the second thin-walled portion 38. In addition, the first sheet member 29 constructing the first thin-walled portion 37 is provided with a through hole 39 at an area opposite to the partitioning wall 17, and a space defined between the first vibrating member 27 and the second vibrating member 28 is vented to atmosphere by the through hole 39.

In such a configuration of the diaphragm 15, rigidity of the second island portion 36 constructing the second vibrating member 28 bonded to the flow channel forming substrate 12 is substantially improved. That is, since there exists the first island portion 32 abutting on the second island portion 36, rigidity of the second island portion 36 is substantially improved. Accordingly, when the piezoelectric element 16 is driven as follows, it is possible to deform the diaphragm 15 favorably with drive of the piezoelectric element 16, to change volume of the pressure generating chamber 11 sufficiently, and to eject ink droplets favorably from each nozzle 13.

Hereupon, as shown in FIGS. 2A and 2B, it is preferable that the width W1 of the first thin-walled portion of the pressure generating chamber 11 in a longitudinal direction is wider than the width W2 of the second thin-walled portion. In addition, although the first sheet member 29 and the second sheet member 33 are formed of identical material in this embodiment, the first sheet member 29 may be formed of softer material than the second sheet member 33. This allows the first vibrating member 27 to be deformed more easily than the second vibrating member 28. Accordingly, deformation of the second vibrating member 28 is not regulated by the first vibrating member 27, and volume of the pressure generating chamber 11 can be favorably changed. Hereupon, with regard to the term “width”, a direction in which the pressure generating chambers 11 are juxtaposed is referred to as a width direction indicating “width” and a direction perpendicular to the width direction in the surface direction of the flow channel forming substrate 12 is referred to as a longitudinal direction.

In addition, it is preferable that at least a width W3 of the first island portion 32 provided in the first vibrating member 27 in a direction in which the pressure generating chambers 11 are juxtaposed, is wider than a width W4 of the second island portion 36 as shown in FIG. 2B. In addition, it is preferable that even in a longitudinal direction of the pressure generating chamber 11, a width of the first island portion 32 is wider than a width of the second island portion 36. That is, it is preferable that the first island portion 32 is formed to be larger than the second island portion 36.

The first island portion 32 plays a role in ensuring the rigidity of the second island portion 36. If the first island portion 32 has abutted on the second island portion 36, it does not need to be positioned with such high accuracy with respect to the second island portion 36. Accordingly, as will be described later, the first island portion 32 can be easily positioned with respect to the second island portion 36, and thus manufacturing efficiency and yield are improved.

In addition, in this embodiment, provided at an area of the diaphragm 15 opposite to the reservoir 18 is a compliance portion 40 which is, just as the second thin-walled portion 38, substantially constructed from only the second sheet member 33 since the second supporting plate 34 is removed through etching. The compliance portion 40 plays a role in absorbing pressure changes in the reservoir 18 by deforming the second sheet member 33 of the compliance portion 40 when pressure in the reservoir 18 changes and thus maintains a constant pressure in the reservoir 18 at all times.

In such an ink jet recording head 10, ink droplets are adapted to be ejected from a given nozzle 13 by changing the volume of each of the pressure generating chambers 11 by the deformation of the piezoelectric element 16 and the diaphragm 15. Specifically, if ink is supplied from an ink cartridge (not shown) to the reservoir 18, the ink is distributed to each of the pressure generating chambers 11 via the ink supplying path 19. In practice, by contracting the piezoelectric element 16 by applying voltage to the piezoelectric element 16, the diaphragm 15 is deformed along with the piezoelectric element 16 to increase the volume of the pressure generating chamber 11, and thus ink is introduced into the pressure generating chamber 11.

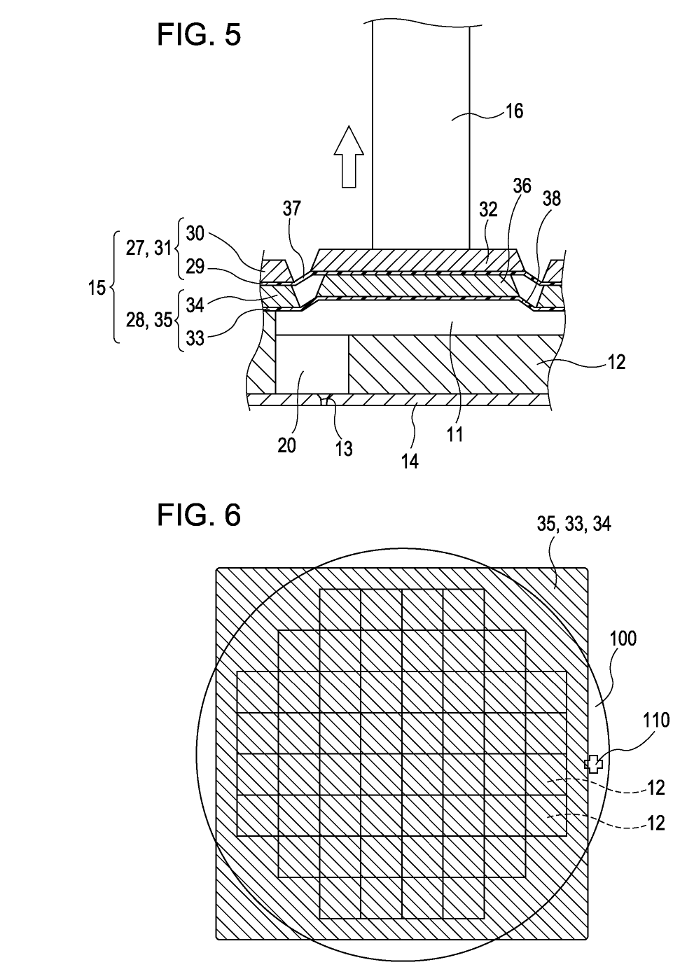

Since the rigidity of the second island portion 36 increases as described above, when contracting the piezoelectric element 16 as such, the diaphragm 15 (the first and second sheet members 29 and 33) is deformed without flexing of the second island portion 36 as shown in FIG. 5 and thus the volume of the pressure generating chamber 11 is sufficiently widened. This allows ink droplets to be ejected from each nozzle 13 favorably.

In detail, after filling ink into the head until ink reaches the nozzle 13, the voltage being applied to the piezoelectric element 16 is released according to a recording signal from a driving circuit. This makes the piezoelectric element 16 expand and return to its original state and also displacement of the diaphragm 15 to return to its original state. As a result, the pressure generating chamber 11 contracts and increases internal pressure and thus, ink droplets are favorably ejected from the nozzle 13.

Incidentally, rigidity of the island portion (the second island portion) can be increased by increasing the thickness of the island portion itself. However, if the island portions are formed in a high density, distance between the island portions is narrowed. For this reason, it is difficult to form the island portions favorably by etching (in particular, wet etching) the supporting plate (the second supporting plate) having a relatively large thickness.

Compared with this, in the invention, since the first vibrating member 27 and the second vibrating member 28 are adapted to be overlapped, the thickness of the second supporting plate 34 can be reduced and thus, it is possible to form the second island portion 36 with high accuracy by etching the second supporting plate 34 favorably. Accordingly, it is possible to improve the ejecting characteristics of the ink droplets ejected from each nozzle 13 and promote uniformity of the ejecting characteristics.

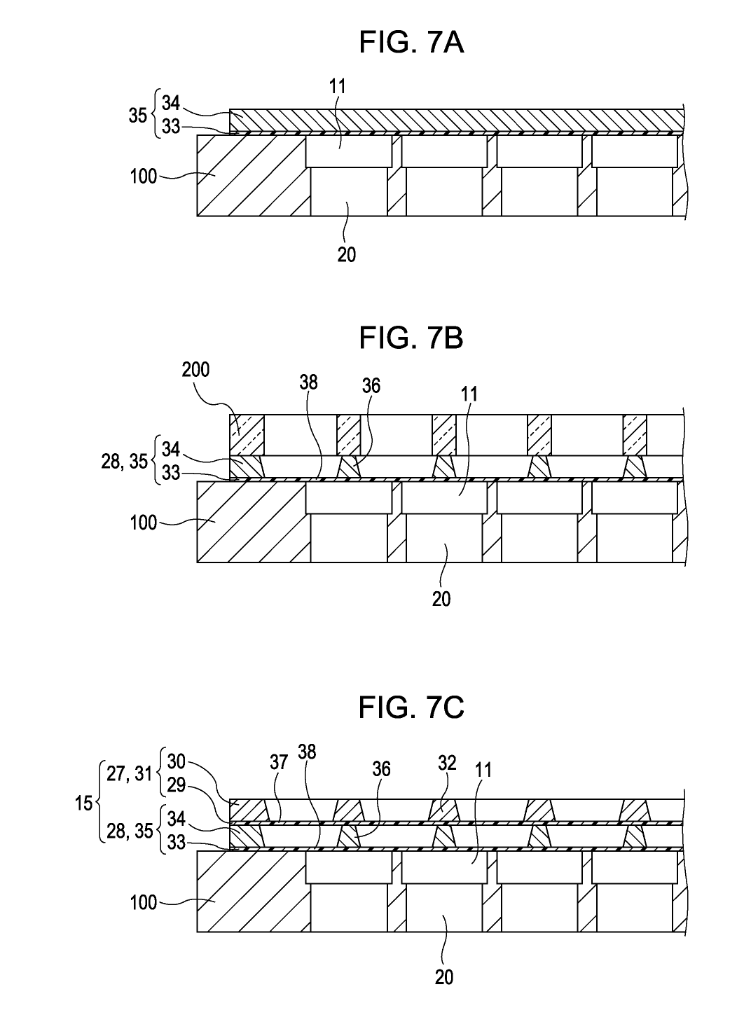

Hereinafter, a method of manufacturing the ink jet recording head according to this embodiment, in particular, a method of forming the diaphragm constructing the ink jet recording head will be described with reference to FIGS. 6, 7A, 7B and 7C.

As a sequence of forming the diaphragm 15, firstly, as shown in FIGS. 6 and 7A, the second composite plate 35 made up of the second sheet member 33 and the second supporting plate 34 constructing the second vibrating member 28 is bonded to a wafer 100 for the flow channel forming substrate. In addition, the wafer 100 for the flow channel forming substrate is a silicon wafer in which a plurality of the flow channel forming substrates 12 are integrally formed, and a flow channel such as the pressure generating chamber 11 is preliminarily formed by etching prior to forming the diaphragm 15. In addition, the second sheet member 33 and the second supporting plate 34 which construct the second composite plate 35 may be sequentially bonded to the wafer 100 for the flow channel forming substrate.

Then, by etching the second supporting plate 34 in a state that the second composite plate 35 is bonded to the wafer 100 for the flow channel forming substrate, as shown in FIG. 7B, the second thin-walled portion 38 and the second island portion 36 are formed. Specifically, for example, a glass mask 200 for etching is positioned on the second supporting plate 34, with taking an alignment mark 110 (see FIG. 6) formed on the wafer 100 for the flow channel forming substrate as a reference. Then, by, for example, wet etching the second supporting plate 34 via the glass mask 200 for etching, the second thin-walled portion 38 and the second island portion 36 are formed. This allows the second thin-walled portion 38 and the second island portion 36 to be formed with high accuracy with respect to the pressure generating chamber 11. In addition, although it is not shown, simultaneously at this time, the compliance portion 40 is also formed.

Next, as shown in FIG. 7C, the first vibrating member 27 made up of the first sheet member 29 and the first supporting plate 30 is bonded onto the second vibrating member 28 in which the second thin-walled portion 38 and the second island portion 36 are formed. That is, prior to bonding to the wafer 100 for the flow channel forming substrate, the first supporting plate 30 is etched to form the first thin-walled portion 37 and the first island portion 32. In addition, in this case, the through hole 39 provided in the first sheet member 29 may be formed at any timing.

Thereafter, the first vibrating member 27 is positioned so that each of the first island portions 32 abuts on each of the second island portions 36, and then bonded to the second vibrating member 28. In this way, the vibrating plate 15 including the first and second vibrating members 27 and 28 is formed.

By forming the vibrating plate 15 in such a sequence, it is possible to considerably improve a positional accuracy of the second island portion 36 and the pressure generating chamber 11 as compared with bonding the second vibrating member 28 and the first vibrating member 27 sequentially to the wafer 100 for the flow channel forming substrate. Accordingly, it is possible to improve the ejecting characteristics of the ink droplets ejected from each nozzle 13 and promote uniformity of the ejecting characteristics.

In addition, as described above, in this embodiment, the first island portion 32 is formed to be larger than the second island portion 36. For this reason, when bonding the first vibrating member 27 to the second vibrating member 28, it is possible to position the first vibrating member 27 relatively easily and bond it to the second vibrating member 28. Accordingly, it is possible to improve work efficiency and yield, and thus promote reduction in cost.

In addition, the through hole 39 is provided in the first sheet member 29 constructing the first vibrating member 27 as described above. With such provision of the through hole 39, it is possible to suppress deformation or breakage of the first sheet member 29 or the second sheet member 33 accompanied by expansion of air due to heating in the manufacturing process, and form the diaphragm 15 favorably. That is, if the through hole 39 is not formed in the first sheet member 29, a space defined between the first vibrating member 27 and the second vibrating member 28 becomes sealed, which may cause a problem that air in the space expands due to heat in the manufacturing process and deforms the first sheet member 29 or the second sheet member 33. However, since the through hole 39 is provided in the first sheet member 29, it is possible to suppress occurrence of such a problem.

In addition, although the first vibrating member 27 is adapted to be bonded onto the second vibrating member 28 in this embodiment, it goes without saying that the first composite plate 31 may be bonded onto the second vibrating member 28 and then, as in case of the second composite plate 35, the first supporting plate 30 may be wet etched to form the first thin-walled portion 37 and the first island portion 32. In this case, it is preferable to form the through hole 39 after forming the first thin-walled portion 37 and the first island portion 32 by wet etching. The reason is that if the through hole 39 is formed prior to etching, an etchant may flow into the second vibrating member 28 side via the through hole 39 and thus etch the second supporting plate 34.

In addition, the wafer 100 for the flow channel forming substrate on which the diaphragm 15 is formed is then divided into each flow channel forming substrate 12. For example, the wafer 100 for the flow channel forming substrate is provided with a weakened portion along a cutting line, and is divided into each flow channel forming substrate 12 by applying external force to the wafer 100 for the flow channel forming substrate. In case of dividing the wafer 100 for the flow channel forming substrate in this way, it is preferable to provide the diaphragm 15 with weakened portions such as notches along the cutting line. This allows the diaphragm 15 to be favorably divided along with the wafer 100 for the flow channel forming substrate.

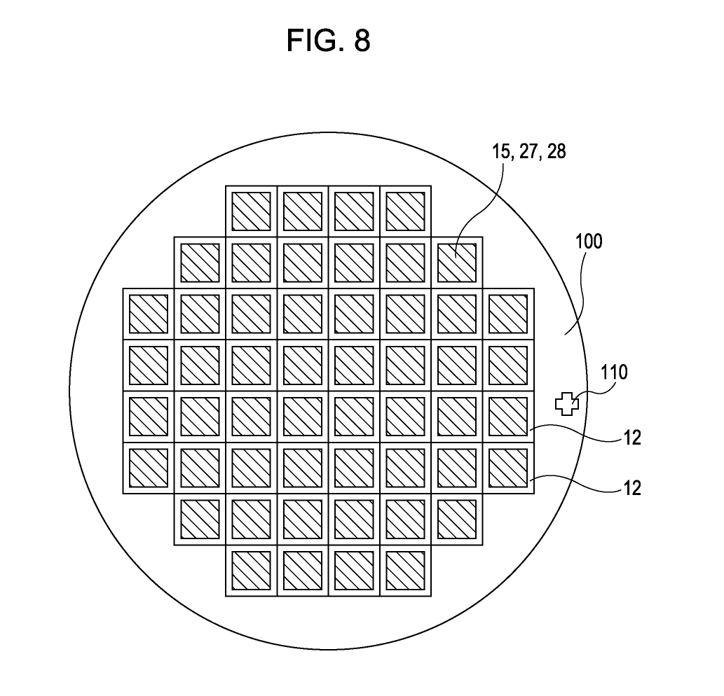

In addition, although the diaphragms 15 are continuously formed at an entire surface of the wafer 100 for flow channel forming substrate in this embodiment, as shown in FIG. 8, for example, each of the diaphragms 15 may be independently formed at an area of the wafer 100 for the flow channel forming substrate opposite to each of the flow channel forming substrates 12. This allows the wafer 100 for the flow channel forming substrate to be favorably divided into each flow channel forming substrate 12.

### Alternative Embodiment

Although the first embodiment of the invention is described in the foregoing, it goes without saying that the invention is not limited to the above description. For example, although an example in which the diaphragm 15 is constructed from two layers (the first vibrating member 27 and the second vibrating member 28) is described in the above-described embodiment, it goes without saying that the diaphragm 15 may be constructed from three or more layers.

In addition, configuration of the ink jet recording head is not limited to the above description. For example, although the first and second thin-walled portions 37 and 38 are continuously provided at an area corresponding to the plurality of pressure generating chambers 11 in the above-described embodiment, it goes without saying that they may be provided independently for every pressure generating chamber 11. In addition, although a nozzle communication hole 20 communicating the pressure generating chamber 11 with the nozzle 13 is provided in the flow channel forming substrate 12 in the above-described embodiment, without being limited to this configuration, the nozzle communication hole 20 may be provided in a separate substrate from the flow channel forming substrate 12.

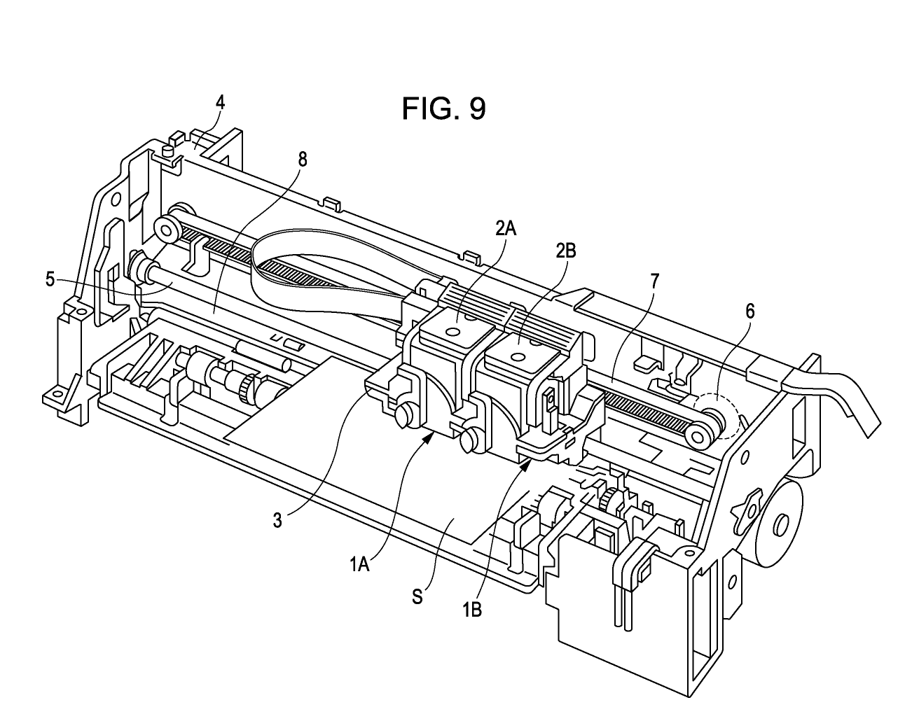

In addition, an ink jet recording head according to this embodiment constitutes a part of a recording head unit including an ink path in communication with an ink cartridge and the like and is mounted on an ink jet recording apparatus. As shown in FIG. 9, the recording head units 1A and 1B in the ink jet recording apparatus are provided with the detachably mounted cartridges 2A and 2B which constitute the ink supplying unit. A carriage 3 on which the recording head units 1A and 1B are mounted is arranged to be able to axially move on a carriage shaft 5 attached to an apparatus main body 4. The recording head units 1A and 1B are, for example, adapted to eject a black ink composition and a color ink composition, respectively.

Then, by transmitting the driving force of a drive motor 6 to the carriage 3 via a plurality of gears (not shown) and a timing belt 7, the carriage 3 on which the recording head units 1A and 1B are mounted moves along the carriage shaft 5. On the other hand, the apparatus main body 4 is provided with a platen 8 along the carriage shaft 5, and a recording sheet S which is a recording medium such as paper fed by a paper feeding roller (not shown) is adapted to be spooled up by the platen 8 and be carried.

In addition, although this embodiment illustrates the ink jet recording head ejecting ink droplets as a liquid ejecting head and the ink jet recording apparatus as a liquid ejecting apparatus, the invention broadly relates to a general liquid ejecting head and a general liquid ejecting apparatus including the liquid ejecting head. As a liquid ejecting head, for example, a recording head used in an image recording apparatus such as a printer, a color material ejecting head used in manufacturing a color filter such as a liquid crystal display, an electrode material ejecting head used in forming an electrode of organic EL display, FED (field emission display) and the like, a bio organic substance ejecting head used in manufacturing a bio chip, etc. may be listed.

What is claimed is:

1. A liquid ejecting head, comprising:
a flow channel forming substrate in which a plurality of pressure generating chambers in communication with nozzles which eject liquid droplets are juxtaposed to each other;
a diaphragm which is provided on the flow channel forming substrate and constitutes one side surface of the pressure generating chamber; and
piezoelectric elements which are provided so that their leading ends abut on the diaphragm,
wherein the diaphragm includes a first vibrating member and a second vibrating member disposed between the first vibrating member and the flow channel forming substrate,
the first vibrating member is formed from a first composite plate made up of a first sheet member and a first supporting plate and has a first island portion which is constructed from the first supporting plate and on which a leading end of the piezoelectric element abuts, and
the second vibrating member is formed from a second composite plate made up of a second sheet member and a second supporting plate and has a second island portion which is constructed from the second supporting plate and arranged at a portion opposite to the first island portion.

2. The liquid ejecting head according to claim 1,
wherein the width of the first island portion is wider than the width of the second island portion at least in a juxtaposing direction of the pressure generating chambers.

3. The liquid ejecting head according to claim 1,
wherein the first sheet member is provided with a through hole and a space defined between the first vibrating member and the second vibrating member is vented to the atmosphere by the through hole.

4. The liquid ejecting head according to claim 1,
wherein the first vibrating member has a first thin-walled portion constructed from the first sheet member at a periphery of the first island portion and the second vibrating member has a second thin-walled portion constructed from the second sheet member at a periphery of the second island portion, and
wherein the width of the first thin-walled portion is wider than the width of the second thin-walled portion.

5. A liquid ejecting apparatus comprising the liquid ejecting head according to claim 1.

6. A method of manufacturing a liquid ejecting head comprising: a flow channel forming substrate in which a plurality of pressure generating chambers in communication with nozzles which eject liquid droplets are juxtaposed to each other; a diaphragm which is provided on the flow channel forming substrate and constitutes one side surface of the pressure generating chamber; and piezoelectric elements which are provided so that their leading ends abut on the diaphragm, wherein the diaphragm includes a first vibrating member and a second vibrating member disposed between the first vibrating member and the flow channel forming substrate, the first vibrating member is formed from a first composite plate made up of a first sheet member and a first supporting plate and has a first island portion which is constructed from the first supporting plate and on which the leading end of the piezoelectric element abuts, and the second vibrating member is formed from a second composite plate made up of a second sheet member and a second supporting plate and has a second island portion which is constructed from the second supporting plate and arranged at a portion opposite to the first island portion,
the method comprising:
forming the second vibrating member on a wafer for the flow channel forming substrate in which a plurality of the flow channel forming substrates are integrally formed;
forming the first vibrating member on the second vibrating member; and
dividing the wafer for the flow channel forming substrate;
wherein in forming the second vibrating member, after bonding the second composite plate made up of the second sheet member and the second supporting plate onto the wafer for the flow channel forming substrate, a mask member is positioned with taking an alignment mark provided on the wafer for the flow channel forming substrate as a reference, and the second island portion is formed by etching the second supporting plate through the mask member.
